(19) United States
(12) Patent Application Publication
(10) Pub. No.: US 2025/0191945 A1
(43) Pub. Date: Jun. 12, 2025

(54) SMART WAFER TRANSPORT CASE WITH SENSOR SYSTEM

(71) Applicant: Taiwan Semiconductor Manufacturing Co., Ltd., Hsinchu (TW)

(72) Inventors: Chung-Hsien LIAO, Hsinchu (TW); Chia-Yu TANG, Hsinchu (TW); Jui-Mu CHO, Hsinchu (TW); Chien-Fang LIN, Hsinchu (TW)

(21) Appl. No.: 18/532,787

(22) Filed: Dec. 7, 2023

(51) Int. Cl. H01L 21/67; G01B 11/26; H01L 21/673

(52) U.S. Cl. CPC H01L 21/67265; G01B 11/26; H01L 21/6735

(57) ABSTRACT

A transport case is configured to hold a plurality of wafers for transport of the wafers. The transport case includes a plurality of slots each configured to receive and hold a respective wafer. The transport case includes a sensor system configured to measure the positions or orientations of wafers within the slots or during loading into the slots. The transport case includes a communication system configured to transmit sensor data from the sensor system to an external control system.

### BACKGROUND

Fabrication of integrated circuits is typically accomplished by performing a large number of processing steps on semiconductor wafers. The processing steps typically result in the formation of a large number of transistors in highly complex arrangements in conjunction with a semiconductor substrate. The processing steps also result in the formation of dielectric layers, metal interconnects, plugs, and other integrated circuit structures and components.

Processing steps may be performed using various tools at a semiconductor fabrication facility. Such tools can include thin-film deposition tools, etching tools, ion implantation tools, annealing tools, planarization tools, cleaning tools, dicing tools, and various other tools. After a process has been performed on a wafer with a particular tool, the wafer may be stored at a storage location or transferred to the location of another tool for a next processing step. The tools and storage facilities may be at various locations within a same fabrication facility, within a same building at the fabrication facility, within different buildings at the fabrication facility, or at a separate fabrication facility.

The wafers may be loaded into a transport case for storage during transfers or for storage between transfers. However, storage and transport of wafer introduces various risks of damage to the wafers. If wafers are damaged, then the integrated circuits that will be diced from the wafers may function poorly or may not function at all. Wafer yields may be reduced and electronic devices that will utilize the integrated circuits may not work properly.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventors' approach to the particular problem, which, in and of itself, may also be inventive.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a semiconductor processing system, in accordance with some embodiments.

FIG. 2 is an illustration of a wafer transport case, in accordance with some embodiments.

FIG. 3A is an illustration of a wafer transport case, in accordance with some embodiments.

FIG. 3B is a side view of a portion of a wafer transport case, in accordance with some embodiments.

FIG. 4 is a side view of a portion of a wafer transport case, in accordance with some embodiments.

FIG. 5 is a top view of a portion of a wafer transport case, in accordance with some embodiments.

FIG. 6 is a side view of a portion of a wafer transport case, in accordance with some embodiments.

FIGS. 7A and 7B are illustrations of a transport case at an unload/load port, in accordance with some embodiments.

FIG. 8 is a block diagram of a semiconductor processing system, in accordance with some embodiments.

FIG. 9 is a flow diagram of a method for operating a semiconductor processing system, in accordance with some embodiments.

FIG. 10 is a flow diagram of a method for operating a semiconductor processing system, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “some embodiments” or “an embodiment” means that a particular feature, structure or characteristic described in connection with the embodiment is included in at least some embodiments. Thus, the appearances of the phrases “in some embodiments” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

Embodiments of the present disclosure help ensure that semiconductor wafers or other sensitive semiconductor processing equipment or materials are not damaged during transport, loading, and unloading. Embodiments of the present disclosure provide a wafer transport case, often termed a front opening unified pod (FOUP), with a sensor system including a plurality of sensors mounted within the transport case. The transport case includes a plurality of slots each configured to receive and hold a wafer. The sensors can detect whether a wafer is tilted in a slot, whether a wafer is centered within the slot, whether a wafer has collided with a frame of the slot, the position of door removal pins at a load/unload port, whether the transport case is tilted, or a variety of other factors related to the loading, unloading, and storing of wafers with a transport case. The transport case also includes a communication system that can transmit sensor data or other alerts to an external control system so that the external control system can take action to prevent damage to wafers based on the sensor data.

The wafer transport case in accordance with embodiments of the present disclosure provides several benefits. The sensor system can detect that wafers are in a position that could result in damage if not addressed. The sensor system can detect misalignment or other risk factors that are present during loading and unloading of wafers. The wafer transport case can transmit sensor data to the external control system so that the external control system can take steps to correct alignment or positioning issues prior to transporting the transport case, unloading wafers, or loading wafers. This ensures that semiconductor wafers and other sensitive equipment are not damaged during transport, loading, or unloading. The result is better functioning integrated circuits and improved wafer yields.

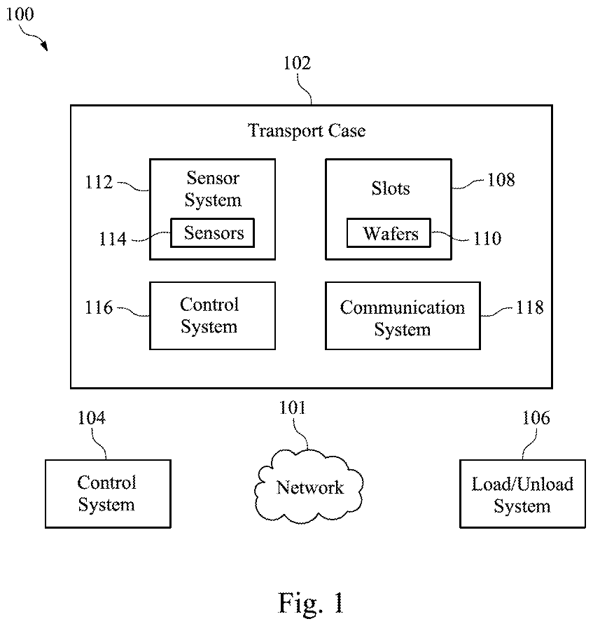

FIG. 1 is a block diagram of a semiconductor processing system 100, in accordance with some embodiments. The semiconductor processing system 100 includes a transport case 102, a control system 104, and a load/unload system 106. As will be set forth in more detail below, the components of the semiconductor processing system 100 cooperate to ensure that semiconductor wafers are safely stored, transported, loaded, and unloaded in conjunction with the transport case 102.

In some embodiments, the transport case 102 is a wafer transport case configured to hold semiconductor wafers 110 before, after, or between semiconductor processes. The transport case 102 includes a plurality of slots 108. Each of the slots 108 is configured to receive and hold a wafer 110. Wafers 110 can be loaded into or unloaded from the transport case 102. Wafers 110 can be transported in the transport case 102, as will be described in more detail below.

In some embodiments, the transport case 102 is a FOUP. The FOUP includes a front cover that can be removed to expose the slots 108. When the front cover is removed, wafers 110 can be loaded into the slots 108 or unloaded from the slots 108. After unloading/loading, the front cover can be replaced. As will be set forth in more detail below, the front cover may include pins slots configured to receive pins from the load/unload system 106. The load/unload system 106 removes or replaces the front cover with the pins positioned in the pins slots.

The semiconductor processing system 100 processes semiconductor wafers 110. The semiconductor wafers 110 undergo a large number of semiconductor processes in order to form integrated circuits within the semiconductor wafers. The semiconductor processes can include forming transistors on a semiconductor substrate within the semiconductor wafers, forming dielectric layers on the semiconductor wafers, forming metal interconnects on the semiconductor wafers, and other processes to form structures and components within the semiconductor wafers. Some of the processes associated with forming the features can include epitaxial growth processes, thin film deposition processes, etching processes, photolithography processes, chemical mechanical planarization (CMP) processes, annealing processes, ion implantation processes, cleaning processes, dicing processes, and various other processes.

The semiconductor processing system 100 may include a plurality of processing tools (not shown) for performing the semiconductor processes on the wafers 110. Examples of tools can include photolithography tools, thin-film deposition tools, etching tools, aligning tools, annealing tools, ion implantation tools, CMP tools, or other types of tools.

During the processing cycle of a wafer 110, a wafer may be loaded into a transport case 102. The transport case 102 may then be transported to a processing tool for a first processing step. The processing tool includes or is coupled to a load/unload system 106. The transport case 102 is positioned at a load/unload port of the load/unload system 106. The load/unload system 106 removes a front cover from the transport case 102. A robot arm of the load/unload system 106 then removes the wafer 110 and places the wafer 110 in the first processing tool. The processing tool then performs a first semiconductor process on the wafer.

After the first semiconductor process has been performed on the wafer 110, the load/unload system 106 loads the wafer 110 back into the transport case 102. In practice, the load/unload system 106 may load the wafer 110 into a different transport case 102. The transport case 102 may then be transported to a second semiconductor tool for a next processing step. Alternatively, the transport case 102 may be transported to a lot storage site and the wafer 110 may be loaded into a stocker. Subsequently, the wafer 110 is unloaded from the stocker into a transport case and transported to a next semiconductor processing tool.

Due to the sensitivity of the wafer 110, it is very beneficial to ensure that no damage or contamination occurs. It is possible that damage can occur during loading of a wafer into the transport case 102, during transport of the wafer 110 in the transport case 102, or during unloading of the wafer 110 from the transport case 102.

In order to reduce or prevent the risk of damage to wafers 110, the transport case 102 includes a sensor system 112. The sensor system 112 monitors the loading of wafers into the transport case 102, monitors the orientation of the wafer is in the transport case 102, monitors the unloading of wafers from the transport case 102, and monitors the orientation of the transport cases itself.

In some embodiments, the sensor system 112 includes a plurality of sensors 114 within or on the transport case 102. The sensors 114 can perform a variety of functions, as will be set forth in more detail below. The sensors 114 can monitor a tilt of the wafer 110 within a slot 108. The sensors 114 can monitor whether an edge of the wafer 110 has collided with a frame of a slot 108. The sensors 114 can monitor whether a wafer 110 is centered within a slot 108. The sensors 114 can monitor whether a wafer during loading is on a trajectory to collide with a frame of a slot 108. The sensors 114 can monitor whether the transport case 102 itself is tilted prior to or during transport or loading/unloading. The sensors 114 can monitor the position and orientation of door removal pins of the load/unload system 106 prior to or during removal of the front cover of the transport case 102. The sensors 114 can perform other types of functions than those described above without departing from the scope of the present disclosure.

In some embodiments, the transport case 102 includes a control system 116. The control system 116 can include one or more processors in one or more memories. The control system 116 can control the sensor system 112. The control system 116 can receive sensor data from the sensor system 112 and can process the sensor data in order to determine whether the sensor data indicates a collision, a bad orientation, tilting, or other issues associated with the transport case 102 and the wafers 110 within the transport case 102. While the control system 116 is shown as separate from the sensor system 112, in practice, the control system 116 may be part of the sensor system 112.

In some embodiments, the transport case 102 includes a communication system 118. The communication system 118 can include one or more wireless transceivers configured to transmit data from the transport case 102. The communication system can also include wired communication systems for transmitting data in a wired manner from the transport case 102. The control system 116 may control the transmission of data from the communication system 118. The control system 116 may also control or monitor the reception of data via the communication system 118.

The control system 104 can correspond to a control system associated with the semiconductor processing system 100. The control system 104 can include processors, memories, and communication systems. The control system 104 may be associated with a particular semiconductor processing tool and may control the function of the semiconductor processing tool including controlling the function of a load/unload system 106 associated with a semiconductor processing tool. The control system 104 may be associated with a transport system that carries the transport case 102 between processing tools or storage sites. The control system 104 may correspond to a general control system that controls a plurality of processing tools or transport systems of the semiconductor processing system 100.

The control system 104 may correspond to a dispersed control system. Portions of the control system may be located at various locations within the semiconductor processing system 100. Portions of the control system 104 may be virtual resources or cloud-based resources external to the physical processing facility associated with the semiconductor processing system 100. Accordingly, processing resources, memory resources, and communication resources of the control system 104 may be dispersed within the semiconductor processing system 100.

The control system 116 of the transport case 102 may control the communication system 118 to transmit data associated with the transport case 102 to the control system 104. The communication system 118 may continuously transmit data associated with the status of the transport case 102 or the wafers 110 carried by the transport case 102 during transport, loading, or unloading of wafers 110.

In some embodiments, the communication system 118 may transmit data to the control system 104 when an alert or warning is to be issued to the control system 104. For example, the control system 116 of the transport case 102 may transmit an alert to the control system 104 when the sensor data indicates that a wafer 110 is tilted, that an edge of a wafer 110 has collided with a frame of a slot 108, that a wafer 110 is not centered within a slot 108, that the transport case 102 is tilted, that pins of a load/unload system 106 are misaligned with corresponding pins slots in a door of the transport case 102, or other types of alerts.

The control system 104 can control or adjust an aspect of the transport case 102 responsive to the data or alerts received from the transport case 102. For example, the control system 104 can control the robot arm to remove a tilted wafer, to adjust a position of a tilted or poorly centered wafer, to remove a wafer that has experienced a collision, to adjust a position of a tilted transport case 102, to stop transport of a transport case 102, to transfer the transport case 102 to an analysis tool so that wafers may be analyzed in response to possible damage. The control system 104 may issue an alert to technicians to manually inspect or adjust aspects of the transport case 102. Accordingly, the control system 104 may take various actions responsive to the alerts or data received from the transport case 102.

The transport case 102, the control system 104, and the load/unload system 106 may be communicatively coupled together via a network 101. The network 101 can include a wireless network, a wired network, a combination of wireless and wired networks, or other types of networks that can facilitate communication between the components of the processing system 100.

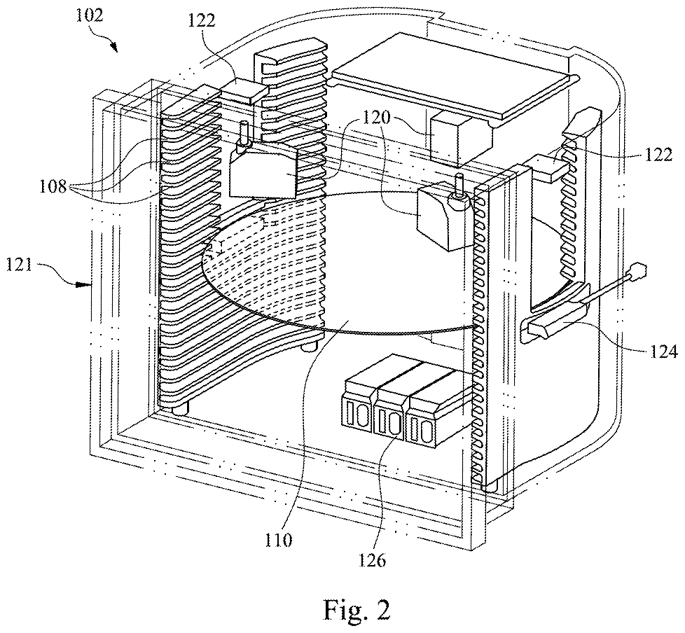

FIG. 2 is an illustration of a transport case 102, in accordance with some embodiments. The transport case 102 of FIG. 2 is one example of a transport case 102 of FIG. 1. The transport case 102 includes a front opening 121. Though not shown in FIG. 2, the transport case 102 may include a removable cover or door that is placed in front opening 121. The removable cover or door can be temporarily removed when wafers are loaded into the transport case 102 or one wafers are unloaded from the transport case 102. The removable door cover can then be replaced one loading/unloading is complete. Further details regarding aspects of the removable door will be provided below.

The transport case 102 includes a plurality of slots 108. In the example of FIG. 2, each slot 108 includes a first portion and a first lateral side of the of the transport case 102 and a second portion and a second lateral side of the transport case 102. When a wafer 110 is positioned in a slot 108, the wafer 110 rests on the first portion and the second portion of the slot 108.

FIG. 2 illustrates a single wafer 110 in one of the slots 108. However, in practice, a plurality of wafers 110 may be stored in the transport case 102. Each wafer 110 may be positioned in a respective slot 108. For example, a plurality of wafers may be loaded into the slots 108. The transport case 102 may be transported by an overhead track or other transport system to a next processing tool. A load/unload system of the processing tool may then remove the front cover and a robot arm may unload the wafers 110 from the transport case 102 into the processing tool.

In FIG. 2, the transport case 102 includes a plurality of sensors. In particular, the transport case 102 includes sensors 120, 122, 124, and 126. The sensors are examples of sensors 114 of a sensor system 112 from FIG. 1. In practice, other sensors may be positioned in the transport case 102. Sensors may be positioned differently than shown in FIG. 2.

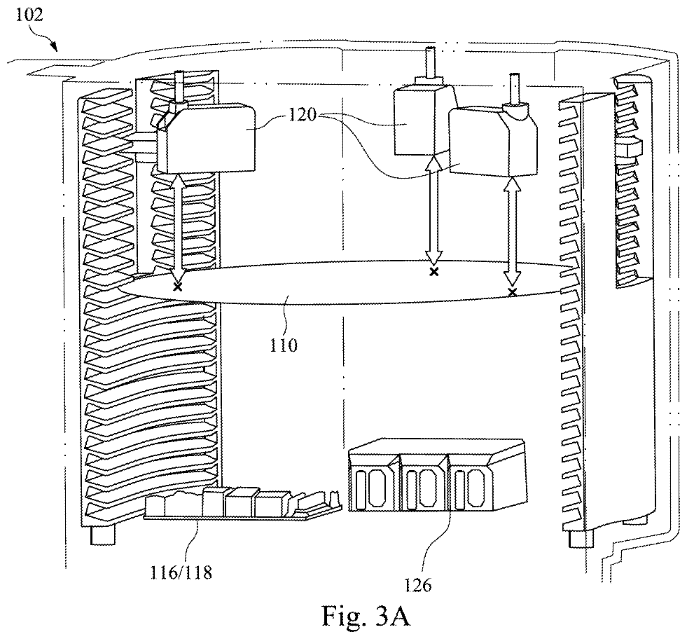

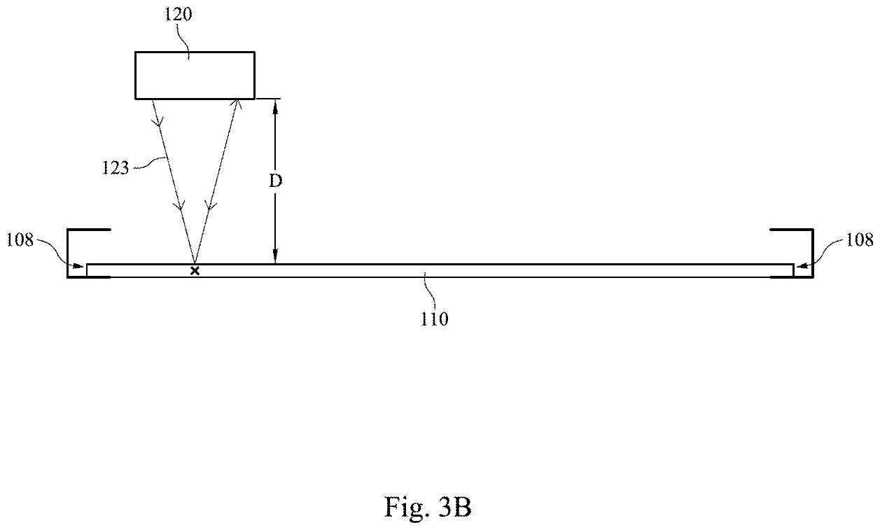

In some embodiments, the sensors 120 correspond to distance sensors. The distance sensors may each be configured to measure a vertical distance between the surface of the wafer 110 and the corresponding sensor 120. The three distance measurements can be utilized to determine a tilt of the wafer 110, as will be described in more detail in relation to FIG. 3A.

In some embodiments, the sensors 122 may correspond to inertial sensors. The inertial sensors can include multiaxis accelerometers, multiaxis gyroscopes, or other types of inertial sensors. The inertial sensors can sense, the vibrations or accelerations, whether a wafer 110 has impacted a frame of a slot 108. The inertial sensors may be positioned differently than shown in FIG. 2. Furthermore, the transport case 102 may include a large number of inertial sensors each coupled to a respective slot 108 or portion of a slot 108. This can assist in detecting whether a particular wafer has impacted a frame of a particular slot 108.

The sensors 124 may correspond to cameras or other types of image sensors. The sensors 124 can include charge coupled devices. The sensors 124 can capture images of the wafers 110 within slots 108. The sensors 124 can generate sensor signals that indicate how centered a wafer 110 is within a slot 108, as will be described in more detail below. In some embodiments, the sensors 124 may capture images of a wafer 110 each time a wafer 110 is loaded into a slot 108. The sensors 124 can be mounted within the transport case 102. A different number of sensors 124 can be included in the transport case 102.

In some embodiments, the sensor 126 may correspond to a leveling sensor. The leveling sensor 126 may detect whether the transport case 102 is tilted or not. The leveling sensor can one or more inertial sensors or gravitational sensors that detect whether a horizontal X-axis and a horizontal Y-axis or both mutually orthogonal to a vertical Z-axis. If the X-axis and the Y-axis are not both orthogonal to the direction of gravity (Z-axis), then the transport case is tilted. Tilting of the transport case during transport or at the load/unload port of the load/unload system 106 can result in damage to the wafers 110. Accordingly, the control system 116 can control the communication system 118 to output an alert that the transport case 102 is tilted. The control system 104 can then take steps to address the tilting. This can include stopping transport, loading, or unloading of the wafers 110. The control system 104 can also output an alert to a technician to adjust or inspect the transport case 102.

Various other types of sensors or various other arrangements of sensors can be implemented within the transport case 102 without departing from the scope of the present disclosure.

In some embodiments, the control system 116 and the communication system 118 are positioned near a bottom of the transport case 102. The control system 116 may receive sensor data from the various sensors. The control system 116 may receive sensor data from the sensors via wired connections (not shown) or via wireless connections. The control system 116 may process the sensor data and an may control the communication system 118 to output data to the external control system 104 as described previously. The control system 116 and the communication system 118 can be positioned or arranged in other ways without departing from the scope of the present disclosure.

FIG. 3A is an illustration of a transport case 102, in accordance with some embodiments. The transport case 102 of FIG. 3A is one example of a transport case 102 of FIGS. 1 and 2. In FIG. 3A, sensors 120 are each measuring a vertical distance between the sensor 120 and a particular point x on the surface of the wafer 110. The three vertical distances can be utilized to determine a tilt of the wafer 110. If the three vertical distances are identical, then the wafer has no tilt. As used herein, no tilt corresponds to the top surface of the wafer 110 lying in a horizontal X-Y plane without a vertical (Z) component. If the three vertical distances are not all identical, then the wafer is tilted.

Each time a wafer 110 is loaded into a slot 108, it is beneficial to monitor whether there is a tilt to the wafer 108. A tilt can be problematic as the wafer 110 may not be in a stable position and may slide or otherwise collide with a frame of a slot 108. A tilt can indicate that there is debris on a bottom surface of the wafer 110 or that there is debris and the frame of the slot 108 on which the wafer 110 rests. A tilt can also indicate that the wafer 110 has been improperly loaded into a slot.

Advantageously, the sensor system 112, utilizing the sensors 120 monitors each wafer 110 when it is loaded into a slot 108 to determine whether a tilt is present. If a tilt is present, or if the tilt exceeds a threshold tilt, then the control system 116 may control the communication system 118 to output an alert to the control system 104 that a wafer is tilted. The control system 104 may then halt loading, unloading, or transport operations so that the tilt can be corrected or otherwise address. This may include alerting a technician to manually inspect the transport case 102 and the wafer 110. This may include transporting the transport case 102 to an inspection tool that may inspect the surface of the wafer or the slot 108 to determine if there is debris, damage, or improper loading of the wafer 110 into the slot 108.

In some embodiments, the wafers 110 are loaded one at the time into the slots 108 in an ascending manner. In other words, if a first wafer is loaded into a first slot 108, a next wafer is loaded into a second slot 108 that is higher than the first slot. If the sensors 120 are positioned above the wafers 110, then this ascending loading enables the sensors 120 can measure the tilt of each wafer 110 as the wafer is loaded into the slot 108.

In some embodiments, the sensors 120 may be positioned at a bottom of the trench port case 102. In this case, the wafers 110 may be loaded in a descending manner such that the sensors 120 may measure the tilt of the bottom surface of each wafer 110 as the wafers are loaded into the transport case 102.

FIG. 3B is a side view of a portion of a transport case 102, in accordance with some embodiments. Only a single slot 108, of a single wafer 110, and a single sensor 120 are shown. The wafer 110 rests on a frame of the slot 108. In the meeting portion of the sensor 120 emits a laser beam 123 onto point x on a top surface of the wafer 110. The laser beam 123 reflects off the top surface and is received by the sensing portion of the sensor 120. The sensor 120 measures a vertical distance D based on the emitted and reflected laser beam 123. Each of the three sensors 120 can be utilized in this manner to determine the respective vertical distance D. Accordingly, in some embodiments, the sensors 120 are laser sensors. The sensors 120 may correspond to other types of ranging sensors without departing from the scope of the present disclosure.

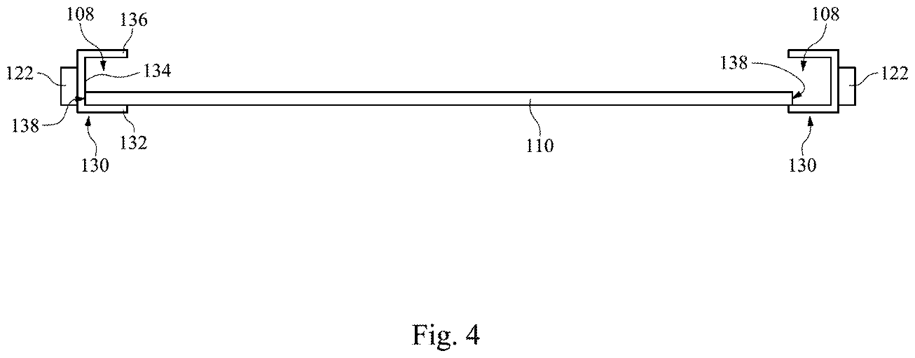

FIG. 4 is a side view of a portion of the transport case 102 in accordance with some embodiments. Only a single slot 108 of a single wafer 110 are shown. The slot 108 includes a frame 130. The frame includes a bottom surface 132, a side surface 134, and the top surface 136. In practice, the top surface 136 may correspond to the bottom portion of a next higher slot 108. The wafer 110 includes a lateral edge 138.

Inertial sensors 122 are coupled to the frame 130 of the slot 108. In practice, the inertial sensors 122 may be positioned in a different manner than shown in FIG. 4. The inertial sensors 122 can detect whether the edge 138 of the wafer 110 has impacted the side surface 134 of the frame 130. In the example of FIG. 4, the lateral edge 138 of the wafer 110 has contacted or collided with the side surface 134 of the frame 130 of the slot 108. The left inertial sensor 122 generates sensor data indicative of the collision. The sensor system 112, or the control system 116 determine that a collision is a current based on the sensor data. The control system 116 can then control the communication system 118 to output an alert indicating that the collision is occurred.

The control system 104 receives the collision alert and can take action responsive to the collision alert. The control system 104 may immediately stop transport of the transport case 102, may stop loading or unloading of wafers 110, or may cause a robot arm of the load/unload system 106 to adjust a position of the wafer 110. In some embodiments, the control system 104 may cause the transport system to transport the transport case 102 to an inspection station inspection tool to determine whether damage has occurred to the wafer 110. The control system 104 commission alert to a technician to manually inspect the wafer 110. This can help ensure that a damage control inspection is performed prior to a next processing step. If damage is detected, then the wafer can be scrapped prior to wasting additional processing steps.

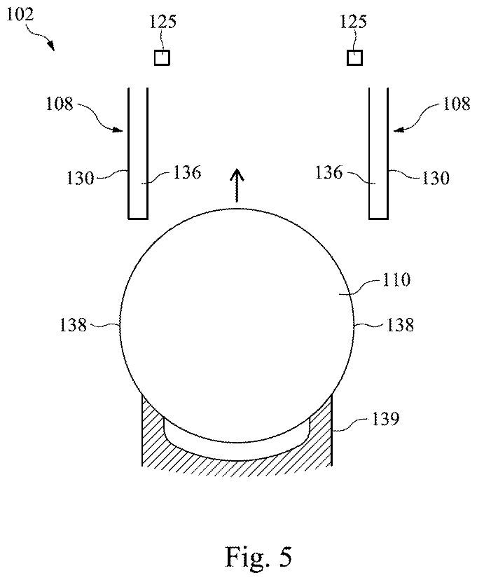

FIG. 5 is a top view of a portion of a transport case 102 during loading of the wafer 110 into the transport case 102, in accordance with some embodiments. FIG. 5 illustrates a portion of a single frame 108. In particular, a portion of a frame 130, including a top portion of a frame 130 is shown in FIG. 5. A robot arm 139 of the load/unload system 106 is carrying the wafer 110 into the slot 108.

Sensors 125 are positioned within the transport case 102. The sensors 125 monitor a trajectory of the wafer 110 during loading. The sensors 125 can detect whether the trajectory of the loading process is aligned to cause a collision of the lateral edge 138 with the frame 130. If the alignment corresponds to a collision trajectory, then the control system 116 can control the communication system 118 to output an alert to the control system 104. The control system 104 can control the robot arm 139 to adjust his position or alignment to avoid the collision. The loading process can then continue safely.

The sensors 125 can include image sensors that capture images or otherwise monitor the position of the wafer 110 during loading. The sensors 125 can be positioned other than shown in FIG. 5. In some embodiments, the sensors 125 can include arranging sensors or other types of sensors. In some embodiments, the sensors 125 can move vertically as additional wafers 110 are loaded into the transport case 102 so that the sensors are in position to measure the alignment or trajectory or orientation of each wafer 110 is the wafer is loaded. Various other configurations or sensor types can be utilized without departing from the scope of the present disclosure.

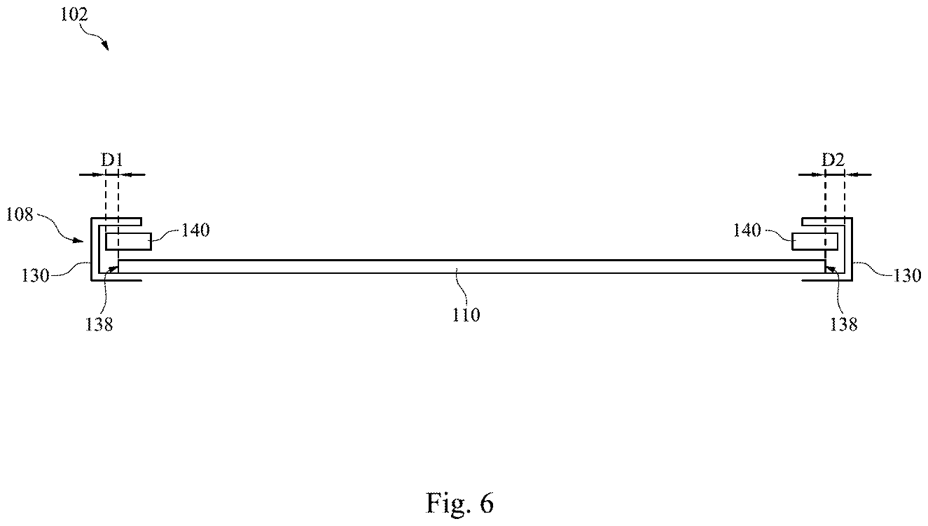

FIG. 6 is a side view of a portion of a transport case 102, in accordance with one embodiment. In FIG. 6, a single slot 108 is shown. A wafer 110 rests on the frame 130 of the slot 108. The transport case 102 includes sensors 140 that measure and orientation of the wafer 110 within the slot 108. The sensors 140 can include image sensors that capture images of the lateral edge 138 of the wafer 110 adjacent to the lateral surfaces of the frame 138 of the slot 108.

In the example of FIG. 6, a first image sensor is positioned on a left side of the wafer 110 and a second image sensor 140 is positioned on the right side of the wafer 110. The first image sensor 140 measures a distance D1 between the lateral edge 138 of the wafer 110 and the left lateral side of the frame 130. The second image sensor 140 measures a distance D2 between the lateral edge 130 of the wafer 110 and the right side of the frame 130. The sensor system 112 or the control system 116 can determine how centered the wafer 110 is within the slot 108 based on the difference between the distances D1 and D2. If D1 and D2 are equal, then the wafer 110 is perfectly centered. The larger the difference between D1 and D2, the less centered the wafer 110 is in the slot 108.

If the difference between D1 and D2 is greater than a threshold difference, then the control system 116 may determine that the wafer 110 is unacceptably uncentered. The control system 116 may control the communication system 118 to output an alert to the control system 104 indicating that the wafer 110 is not centered. The control system 104 can then take action to correct or otherwise address the centering of the wafer 110. The action can include controlling a robot arm 139 to adjust a position of the wafer 110. The action can include stopping transport or loading/unloading operations so that the position of the wafer 110 can be adjusted so that a collision or other damage does not occur. The action can include outputting an alert to a technician so that an inspection or adjustment can take place. The image sensors 140 can be the same as the sensors 125. In other words, the monitoring described in relation to FIGS. 5 and 6 can be performed by the same sensors.

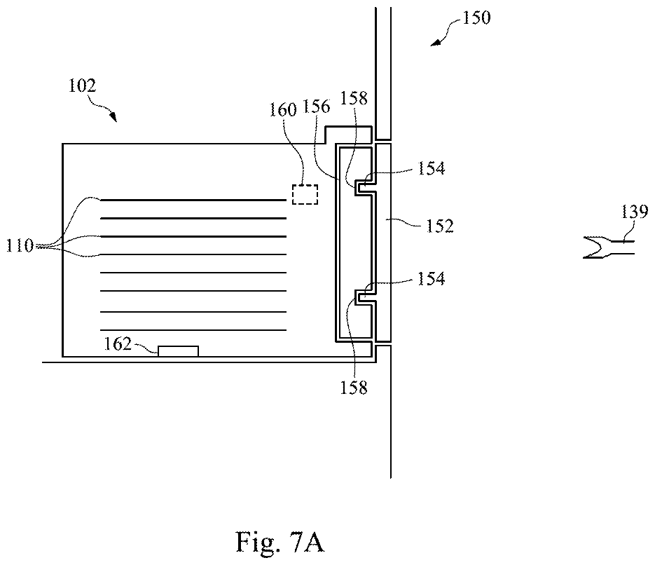

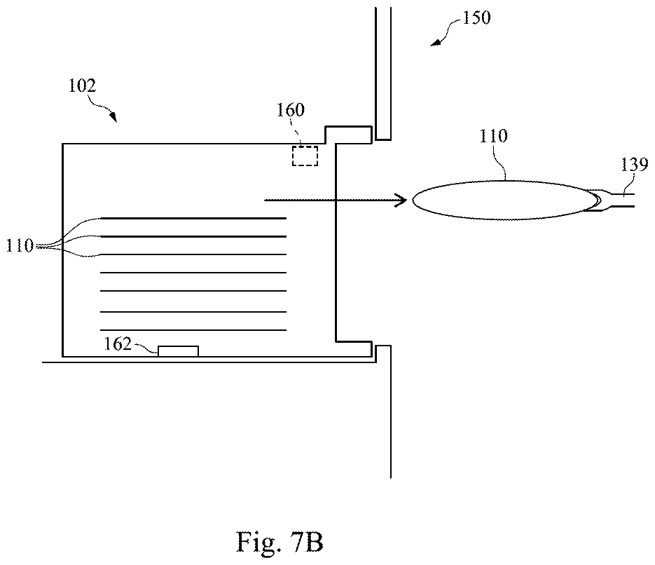

FIG. 7A is a side view of a wafer transport case 102 at a load/unload port 150 of a load/unload station 106, in accordance with some embodiments. The load/unload port 150 can be a load/unload port at a semiconductor processing tool, as described previously.

When the transport case 102 arrives at the load/unload port 150, the transport case 102 is positioned in front of the porch 150. A front cover 156 is positioned at the front of the transport case 102. The front cover 156 includes pin slots 158 that enable removal of the front cover 156.

The load/unload port 150 includes a front cover removal device 152. The front cover removal device 152 is configured to remove the front cover 156 of the transport case 102. In particular, the front cover removal device 152 includes pins 154. The pins 154 are configured to be positioned within the pin slots 158 of the front cover 156. The pins 154 mate with the slots 158. The front cover removal device 152 then removes the front cover 156 of the transport case 102 so that wafers 110 can be unloaded from (or loaded into, as the case may be) the transport case 102 by the robot arm 139.

The transport case 102 includes sensors 160 that monitor the alignment of the pins 152 with the slots 154. If the alignment is not proper, then removal of the front cover 156 may fail. Alternatively, if alignment is not proper, removal of the front cover 156 may cause jarring of the transport case 102, this can possibly damage wafers 110.

Accordingly, the sensors 160 measure or detect the positioning or alignment of the pins 152 relative to the pin slots 158. If there is misalignment, the control system 116 can control the communication system 118 to output an alert or alignment data to the control system 104. The control system 104 can then adjust either the position of the transport case 102 relative to the unload/unload port 150 or can adjust the position of the front cover removal device 152 so that the pins 154 are better aligned with the pin slots 158.

In some embodiments, the sensors 160 can assist in a calibration process for the load/unload port 150. Based on the measured alignment, the control system 104 can automatically adjust a position of either a next transport case 102 or of the cover removal device 152. This calibration data can be passed to other load/unload systems 106 of the processing system 102 so that proper pin alignment can be automatically performed each time a transport case 102 is brought to a load/unload port 150.

In some embodiments, the sensors 160 correspond to image sensors or other types of ranging sensors that can sense the alignment or position of the pins 154 within the slots 158. The sensors 160 may be moved into position to sense the alignment of the pins when the transport case 102 arrives at the load/unload port 150. Other types of sensors can be utilized without departing from the scope of the present disclosure.

In FIG. 7B, the front cover 156 has been removed by the cover removal device 152. The robot arm 139 is unloading a wafer 110 from the transport case 102. The sensors 160 have been moved so that the wafers 110 can be freely accessed by the robot arm 139. After all of the wafers 110 have been loaded, the front cover removal device 152 can replace the front cover 156 and to the transport case 102.

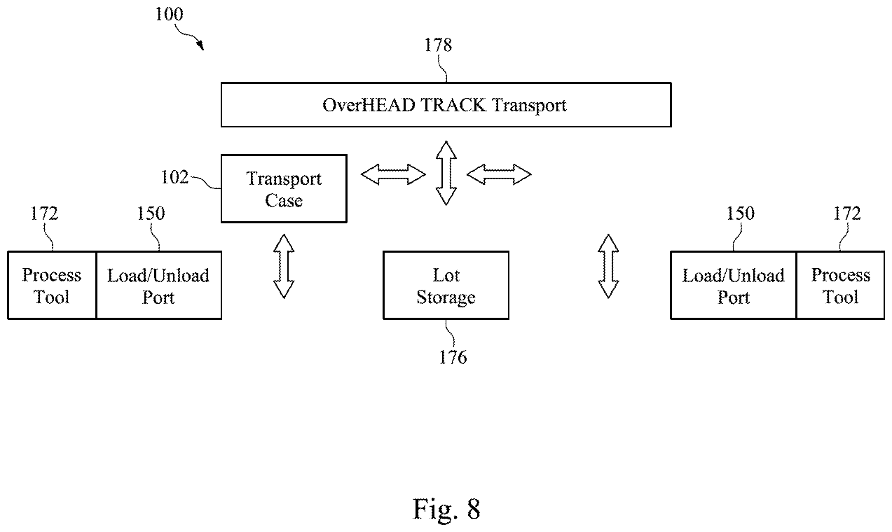

FIG. 8 is a block diagram of a semiconductor processing system 100, in accordance with some embodiments. The semiconductor processing system 100 of FIG. 8 is one example of a semiconductor processing system 100 of FIG. 1. FIG. 8 illustrates two semiconductor process tools 172. A load/unload port 150 of a load/unload system 106 is coupled to or as part of each process tool 172. FIG. 8 also illustrates a lot storage 176. The lot storage can include a wafer stocker or other type of storage that can either store transport cases 1024 can store wafers 110 that have been unloaded from transport cases 102 prior to a next semiconductor process.

FIG. 8 illustrates an overhead track transport 178. The overhead track transport 178 is configured to carry transport cases 102 between the process tools 172 or between the lot storage 176 and the process tools 172. In one illustrative example, a transport case 102 is carried by the overhead track transport 178 to a load/unload port 150 of the process tool 172 and the left. Transport case 102 is lowered and positioned at the load/unload port 150. The front cover is removed and the wafers 110 are unloaded from the transport case 102 into the process tool 172. The process tool 172 that performs the first semiconductor process on the wafers 110.

The load/unload port 150 then loads the wafers 110 from the process tool 172 into a transport case 102. This may be the same transport case or different transport case from before. The overhead track transport then carries the transport case 102 to a lot storage 176. The wafers 110 are unloaded from the transport case 102 into a wafer stocker of the lot storage 176. When the wafers 110 are ready for the next semiconductor process, the overhead track carries a transport case 102 to the lot storage 176 and the wafers one loaded into the transport case 102. The overhead track transport 178 then carries the transport case 102 to the load/unload port 150 of the process tool 172 on the right side. The wafers 110 are then unloaded and the second semiconductor process is performed on wafers.

During loading/unloading and transports of the wafers 110 with the transport case 102, the sensor system 112 of the transport case 102 performs the measuring, detecting, and monitoring described previously. The control system 104 can control the components of the system 100 to address or adjust aspects of the transport case 102 responsive to alerts provided by the transport case based on the sensor system 112. Other types of transport systems can be utilized without departing from the scope of the present disclosure.

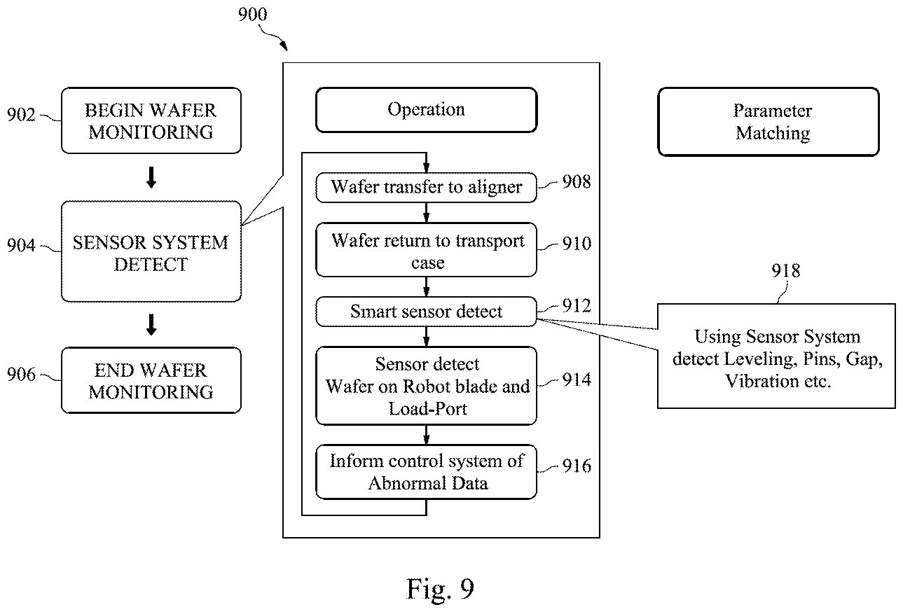

FIG. 9 is a flow diagram of a method 900 for operating a semiconductor processing system 100, in accordance with some embodiments. The method 900 can utilize systems, components, and processes described in relation to FIGS. 1-8. At 902, wafer monitoring begins by the sensor system 112 of a transport case 102. At 904, the method 900 includes utilizing a sensor system to detect improper alignment or orientation of wafers 110 and the transport case 102. The step 904 can include the steps 908-918. In particular, at 908, wafers 110 are transferred to an aligner. At 910, the wafers are loaded back into the transport case 102. At 912/918, the sensors 114 of the sensor system 112 of the transport case 102 detect leveling, pin alignment, centering gaps, vibrations, etc., as described previously. At 914, the sensors monitor the wafer 110 on the robot arm 139 at the load/unload port 150, as described previously. At 916, the control system 116 of the transport case 102 informs the control system 104 of the processing system 100 of any alerts or abnormal data, as described previously. The control system 104 can then take corrective action, as described previously.

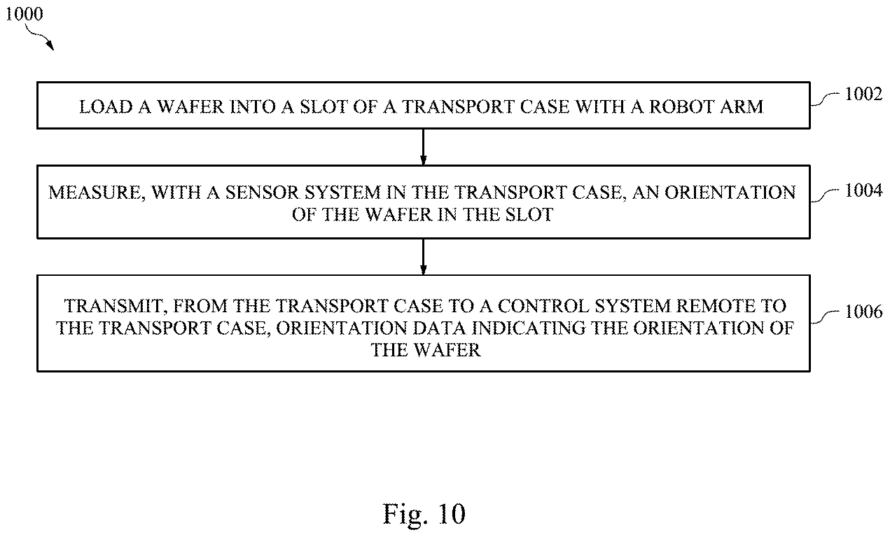

FIG. 10 is a flow diagram of a method 1000 for operating a semiconductor processing system, in accordance with some embodiments. The method 1000 can utilize systems, components, and processes described in relation to FIGS. 1-9. At 1002, a wafer is loaded into a slot of a transport case with a robot arm, in accordance with some embodiments. One example of a wafer is a wafer one of FIG. 1. One example of a slot is a slot 108 of FIG. 1. One example of a transport case is a transport case 102 of FIG. 1. One example of a robot arm is a robot arm 139 of FIG. 7B. At 1004, the method 1000 includes measuring, with a sensor system in the transport case, an orientation of the wafer in the slot. One example of a sensor system is the sensor system 112 of FIG. 1. At 1006, the method 1000 includes transmitting, from the transport case to a control system remote to the transport case, orientation data indicating the orientation of the wafer. One example of a control system is the control system 104 of FIG. 1.

Embodiments of the present disclosure help ensure that semiconductor wafers or other sensitive semiconductor processing equipment or materials are not damaged during transport, loading, and unloading. Embodiments of the present disclosure provide a wafer transport case, often termed a front opening unified pod (FOUP), with a sensor system including a plurality of sensors mounted within the transport case. The transport case includes a plurality of slots each configured to receive and hold a wafer. The sensors can detect whether a wafer is tilted in a slot, whether a wafer is centered within the slot, whether a wafer has collided with a frame of the slot, the position of door removal pins at a load/unload port, whether the transport cases tilted, or a variety of other factors related to the loading, unloading, and storing of wafers with a transport case. The transport case also includes a communication system that can transmit sensor data or other alerts to an external control system so that the external control system can take action to prevent damage to wafers based on the sensor data.

The wafer transport case in accordance with embodiments of the present disclosure provides several benefits. The sensor system can detect that wafers are in a position that could result in damage if not addressed. The sensor system can detect misalignment or other risk factors that are present during loading and unloading of wafers. The wafer transport case can transmit sensor data to the external control system so that the external control system can take steps to correct alignment or positioning issues prior to transporting the transport case, unloading wafers, or loading wafers. This ensures that semiconductor wafers and other sensitive equipment are not damaged during transport, loading, or unloading. The result is better functioning integrated circuits and improved wafer yields.

In one embodiment, a method includes loading a wafer into a slot of a transport case with a robot arm, measuring, with a sensor system in the transport case, an orientation of the wafer in the slot, and transmitting, from the transport case to a control system remote to the transport case, orientation data indicating the orientation of the wafer.

In one embodiment, a transport case includes a plurality of slots each configured to receive and hold a respective wafer and a loading face configured to enable loading and unloading of the wafers from the slots. The transport case includes a sensor system configured to measure, for each slot, an orientation of the wafer within the slot and a communication system configured to transmit orientation data indicative of the orientation of the wafer within the slot from the transport case to a control system remote from the transport case.

In one embodiment, a system includes a transport case. The transport case includes a plurality of slots each configured to receive and hold a wafer, a plurality of sensors each configured to generate sensor data, and a communication system configured to transmit the sensor data. The system includes a control system configured to receive the sensor data and to control adjustment an aspect of the transport case responsive to the sensor data.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
loading a wafer into a slot of a transport case with a robot arm;
measuring, with a sensor system in the transport case, an orientation of the wafer in the slot; and
transmitting, from the transport case to a control system remote to the transport case, orientation data indicating the orientation of the wafer.

2. The method of claim 1, wherein measuring the orientation includes a tilt of the wafer including measuring a first vertical distance to a first point on the wafer, measuring a second vertical distance to a second point on the wafer, and measuring a third vertical distance to a third point on the wafer.

3. The method of claim 2, further comprising:
measuring the first vertical distance with a first laser sensor of the sensor system in the transport case;
measuring the second vertical distance with a second laser sensor of the sensor system in the transport; and
measuring the third vertical distance with a third laser sensor of the sensor system in the transport; and
calculating the tilt of the wafer based on the first vertical distance, the second vertical distance, and the third vertical distance.

4. The method of claim 1, detecting, with the sensor system while loading the wafer into the slot, whether an edge of the wafer is aligned to collide with a frame of the slot.

5. The method of claim 4, further comprising transmitting an indication to the control system that the edge of the wafer is aligned to collide with the frame of the slot responsive to detecting that the wafer is aligned to collide with the edge of the slot.

6. The method of claim 5, further comprising controlling, with the control system responsive to the indication, the robot arm to adjust an alignment of the wafer to avoid a collision of the edge of the wafer with the frame of the slot.

7. The method of claim 1, wherein measuring the orientation includes measuring how centered the wafer is within the slot, including:
capturing, with a camera of the sensor system, an image of an edge of the wafer in the slot; and
determining, with the sensor system based on the image, how centered the wafer is within the slot.

8. The method of claim 1, comprising:
measuring, with the sensor system, a tilt of the transport case; and
transmitting, to the control system, transport case tilt data indicating the tilt of the transport case.

9. The method of claim 8, further comprising measuring the tilt of the transport case with a leveling sensor of the sensor system.

10. The method of claim 8, further comprising:
comparing the tilt of the transport case to a tilt threshold; and
outputting, with the control system, an alert that the transport case is tilted if the tilt of the transport case is greater than the tilt threshold.

11. The method of claim 1, further comprising detecting, with the sensor system, positions of door transfer pins of a load/unload port prior to removing a door of the transport case with the door transfer pins.

12. A transport case, comprising:
a plurality of slots each configured to receive and hold a respective wafer;
a loading face configured to enable loading and unloading of the wafers from the slots;
a sensor system configured to measure, for each slot, an orientation of the wafer within the slot; and
a communication system configured to transmit orientation data indicative of the orientation of the wafer within the slot from the transport case to a control system remote from the transport case.

13. The transport case of claim 12, wherein the orientation of the wafer corresponds to a tilt of the wafer, wherein the sensor system is configured to measure, for each slot, the tilt of the wafer within the slot, the sensor system including:
a first distance sensor configured to measure a first distance to a first point on the wafer within the slot;
a second distance sensor configured to measure a second distance to a second point on the wafer within the slot; and
a third distance sensor configured to measure a third distance to a first point on the wafer within the slot, wherein the sensor system is configured to measure the tilt based on the first distance, the second distance, and the third distance.

14. The transport case of claim 12, wherein the sensor system is configured to detect for each slot, whether an edge of the wafer is aligned to collide with a frame of the slot while being loaded into the slot by a robot arm.

15. The transport case of claim 14, wherein the sensor system includes an edge alignment sensor that moves within the transport case to perform edge detection at whichever slot is currently receiving a wafer.

16. The transport case of claim 12, wherein the orientation of the wafer corresponds to how centered the wafer is within the slot, wherein the sensor system includes one or more cameras configured to capture, for each slot, an image of a relative position of an edge of the wafer within slot.

17. The transport case of claim 12, wherein the sensor system includes a leveling sensor configured to detect a tilt of the transport case.

18. A system, comprising:
a transport case including:
a plurality of slots each configured to receive and hold a wafer;
a plurality of sensors each configured to generate sensor data; and
a communication system configured to transmit the sensor data; and
a control system configured to receive the sensor data and to control adjustment an aspect of the transport case responsive to the sensor data.

19. The system of claim 18, further comprising a robot communicatively coupled to the control system, wherein the robot is configured to adjust the aspect of the transport case under control of the control system responsive to the sensor data.

20. The system of claim 18, further comprising an overhead track transport system configured to carry the transport case.
